(19) United States
(12) Patent Application Publication
(10) Pub. No.: US 2024/0384387 A1
(43) Pub. Date: Nov. 21, 2024

(54) MASK, DISPLAY PANEL AND DISPLAY DEVICE

(71) Applicants: Chongqing BOE Display Technology Co., Ltd., Chongqing (CN); BOE Technology Group Co., Ltd., Beijing (CN)

(72) Inventor: Liyuan XU, Beijing (CN)

(73) Assignees: Chongqing BOE Display Technology Co., Ltd., Chongqing (CN); BOE Technology Group Co., Ltd., Beijing (CN)

(21) Appl. No.: 18/272,105

(22) PCT Filed: Apr. 26, 2022
(86) PCT No.: PCT/CN2022/089358

§ 371 Date: Jul. 13, 2023

(51) Int. Cl. C23C 14/04; H10K 59/12; H10K 71/10; H10K 71/16

(52) U.S. Cl. CPC C23C 14/042; H10K 59/1201; H10K 71/166; H10K 71/191

(57) ABSTRACT

The disclosure relates to a mask, a display panel, and a display device. The mask (1) is provided with a plurality of first openings (121) at intervals on the mask body (12), and is equipped with the mask bars (13) having a plurality of second openings (131) at intervals corresponding one-to-one to the plurality of first openings (121), the mask bar (13) is disposed on a side of the mask body, the second openings (131) have same position, shape and size with any one type of the graphic units, and orthographic projections on the mask body (12) of the second openings (131) corresponding to the multiple types of the graphic units are located in the first openings (121).

### CROSS-REFERENCE TO RELATED APPLICATION

The present application is based upon International Application No. PCT/CN2022/089358, filed on Apr. 26, 2022, and the entire contents thereof are incorporated herein by reference.

### TECHNICAL FIELD

The present disclosure relates to the field of display technology, and in particular, to a mask, a display panel and a display device.

### BACKGROUND

In the field of display, due to its excellent characteristics, OLED display is considered to be the new application technology of the next generation of flat panel display. With the continuous pursuit of people's quality of life, OLED display panels have developed rapidly.

It should be noted that, information disclosed in the above background portion is provided only for better understanding of the background of the present disclosure, and thus it may contain information that does not form the prior art known by those ordinary skilled in the art.

### SUMMARY

The purpose of the present disclosure is to provide a mask, a display panel and a display device.

According to one aspect of the present disclosure, a mask is provided for forming different patterns to be formed on a display panel, each of the patterns to be formed includes a plurality of graphic units arranged at intervals, and the graphic units are arranged in multiple types, wherein, the mask includes a mask body and a mask bar, the mask body is provided with a plurality of first openings at intervals; and the mask bar is provided with a plurality of second openings at intervals corresponding one-to-one to the plurality of first openings, the mask bar is disposed on a side of the mask body, the second openings have same position, shape and size with any one type of the graphic units, and orthographic projections on the mask body of the second openings corresponding to the multiple types of the graphic units are located in the first openings.

In one embodiment of the present disclosure, the mask includes a light-shielding area corresponding to a non-display area, adjacent orthographic projections in one first opening of the second openings corresponding to the multiple types of the graphic units in the light-shielding area are partly overlapped or not overlapped.

In one embodiment of the present disclosure, the mask includes a pattern area corresponding to a display area, adjacent second openings corresponding to part types of the graphic units in the pattern area are partly overlapped or not overlapped, and the second openings corresponding to another part types of the graphic units are overlapped with the second openings corresponding to part types of the graphic units.

In one embodiment of the present disclosure, the orthographic projections of the second openings corresponding to the multiple types of graphic units in the first opening are arranged along a first direction, and a size in the first direction of the first opening is greater than or equal to a sum of sizes in the first direction of the orthographic projections of the second openings corresponding to the multiple types of graphic units.

In one embodiment of the present disclosure, the size in the first direction of the first opening located in the pattern area is greater than or equal to a sum of sizes in the first direction of the orthographic projections of the second openings corresponding to part types of the graphic units.

In one embodiment of the present disclosure, the mask bar includes a plurality of mask bars with different magnetic permeability, and the plurality of mask bars with different magnetic permeability are arranged on different regions of the mask body.

In one embodiment of the present disclosure, the mask body includes a first region and a second region adjacently arranged, and the mask bars with different magnetic permeability includes an iron-nickel-cobalt alloy mask bar and a stainless steel mask bar, the iron-nickel-cobalt alloy mask bar is disposed in the first region, and the stainless steel mask bar is disposed in the second region.

In one embodiment of the present disclosure, the mask body is provided with a first groove, the first groove is arranged in the light-shielding area, the first groove is disposed around the pattern area, and is located in the light-shielding area.

In one embodiment of the present disclosure, a second groove is provided between two adjacent first grooves.

According to another aspect of the present disclosure, a display panel is provided, in which patterns to be formed are prepared by the mask according to one aspect of the present disclosures, and different patterns to be formed are prepared by different masks, and the second openings of the different masks have same position, shape and size with corresponding graphic units.

In one embodiment of the present disclosure, the display panel includes a driving backplane, the patterns to be formed are disposed on the driving backplane, and the multiple types of graphic units includes graphic units of an auxiliary layer and graphic units of a light-emitting layer; and the display panel further includes a display area, in the display area, the graphic units of the light-emitting layer are not overlapped with each other, and the graphic units of the auxiliary layer are disposed between the graphic units of the light-emitting layer and the driving backplane.

In one embodiment of the present disclosure, the display panel further includes a non-display area, and in the non-display area, the graphic units of the auxiliary layer and the graphic units of the light-emitting layer are not overlapped with each other.

In one embodiment of the present disclosure, an alignment mark for aligning the second openings with the graphic units is provided on the driving backplane, and the alignment mark is located in the non-display area.

In one embodiment of the present disclosure, the alignment mark includes at least one first alignment mark, a plurality of second alignment marks and a third alignment mark, the at least one first alignment mark is arranged along the first direction; the plurality of second alignment marks corresponds to the multiple types of graphic units one by one, the plurality of second alignment marks are arranged along a second direction, and the second direction is intersected with the first direction; and the third alignment mark is located at an intersection of the first direction and the second direction.

In one embodiment of the present disclosure, the driving backplane includes a metal layer in the non-display area, and the alignment mark is a recess provided on the metal layer.

In one embodiment of the present disclosure, the driving backplane includes a base substrate, a gate, and source and drain electrodes in the display area, the gate is disposed on a side of the base substrate, the source and drain electrodes are disposed on a side of the gate away from the base substrate, the metal layer includes a first metal layer and a second metal layer, the first metal layer is disposed in a same layer with a same material with the gate, the second metal layer is disposed in a same layer with a same material with the source and drain electrodes, and the recess is disposed in the first metal layer and/or the second metal layer.

According to yet another aspect of the present disclosure, a display device is provided, including the display panel described in another aspect of the present disclosure.

Itis to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of the present disclosure, and those skilled in the art can obtain other drawings according to these drawings without creative efforts.

FIG. 1 is a schematic structural diagram of a display panel involved in an embodiment of the present disclosure.

FIG. 2 is a schematic diagram of forming a pixel layer on a driving backplane according to an embodiment of the present disclosure.

FIG. 3 is a schematic diagram of matching of a mask without differentiated magnetic permeability, a driving backplane and a magnetic spacer according to an embodiment of the present disclosure.

FIG. 4 is a schematic diagram of the overall structure of a mask involved in an embodiment of the present disclosure.

FIG. 5 is a schematic diagram of a partial structure of a mask involved in an embodiment of the present disclosure.

FIG. 6 is a schematic diagram of a partial structure of a mask body according to an embodiment of the present disclosure.

FIG. 7 is a schematic distribution diagram of the orthographic projection in the first opening of the second opening of the pattern area according to an embodiment of the present disclosure.

FIG. 8 is another schematic distribution diagram of the orthographic projection in the first opening of the second opening of the pattern area according to an embodiment of the present disclosure.

FIG. 9 is a schematic distribution diagram of the orthographic projection in the first opening of the second opening of the light-shielding area according to an embodiment of the present disclosure.

FIG. 10 is a schematic diagram of the matching of the magnetically permeable mask, the driving backplane and the magnetic spacer according to an embodiment of the present disclosure.

FIG. 11 is a schematic diagram after a mask forming the graphic units in a non-display area of a display panel according to an embodiment of the present disclosure.

### DETAILED DESCRIPTION

Example embodiments will now be described more fully with reference to the accompanying drawings. Example embodiments may, however, be embodied in many forms and should not be construed as limited to the embodiments set forth herein; rather, these embodiments are provided so that this disclosure will be thorough and complete, and will fully convey the concept of example embodiments to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

Although relative terms such as “upper” and “lower” are used in this specification to describe the relative relationship of one illustrated component to another component, these terms are used in this specification only for convenience, for example, according to the exemplary direction shown in the accompanying drawings directions. It will be appreciated that if the illustrated device is turned over so that it is upside down, then elements described as being “upper” will become elements that are “lower”. When a structure is “on” another structure, it may mean that a structure is integrally formed on another structure, or that a structure is “directly.” placed on another structure, or that a structure is “indirectly” placed on another structure through another structure. other structures.

The terms “a”, “an”, “the”, “said” and “at least one” are used to indicate the presence of one or more elements/components/etc.; the terms “comprising” and “have” are used to indicate an open enclosure and means that there may be additional elements/components/etc. in addition to the listed elements/components/etc.; and the terms “first”, “second” and “third” etc. are only used as a marker, not a limit on the number of its objects.

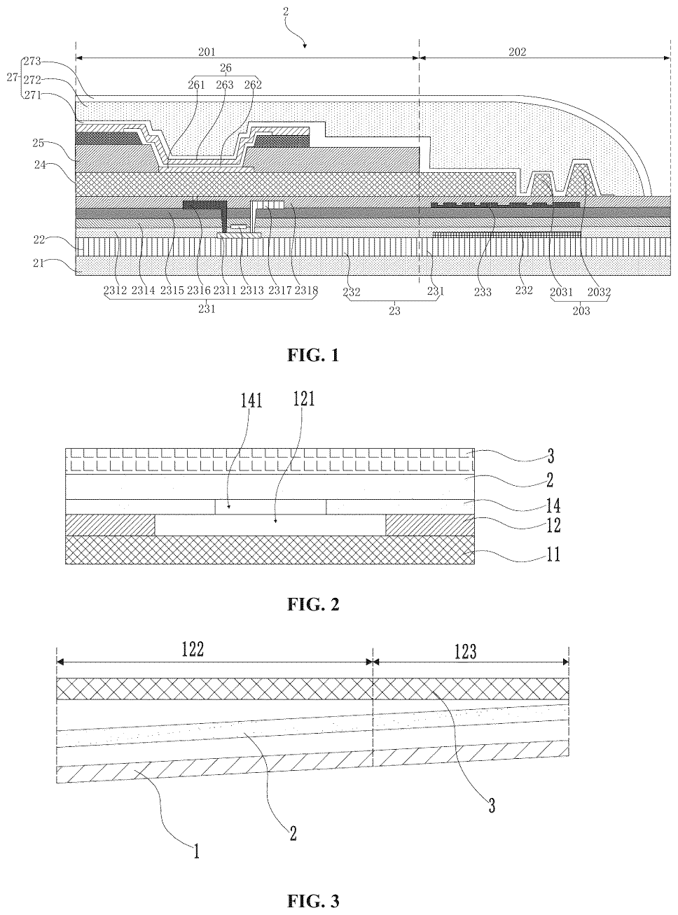

As shown in FIG. 1, the display panel 2 includes a driving backplane, and the driving backplane may include a base substrate 21 and a plurality of thin film transistors 231. The thin film transistor 231 can be a top-gate type or a bottom-gate type. Taking the top-gate type thin film transistor 231 as an example, the thin film transistor 231 can include an active layer 2311, a gate insulating layer 2312, a gate 2313, and a source and drain.

The active layer 2311 is disposed on one side of the base substrate 21, and its material may be polysilicon, amorphous silicon, etc., and the active layer 2311 may include a channel region and two doped regions of different doping types located on both sides of the channel region.

The gate insulating layer 2312 can cover the active layer 2311 and the base substrate 21, and the material of the gate insulating layer 2312 is an insulating material such as silicon oxide.

The gate 2313 is arranged on the side of the gate insulating layer 2312 away from the base substrate 21, and is opposite to the active layer 2311, that is, the projection of the gate 2313 on the base substrate 21 is located within the range of the projection of the active layer 2311 on the base substrate 21. For example, the projection of the gate 2313 on the base substrate 21 coincides with the projection of the channel region of the active layer 2311 on the base substrate 21.

The thin film transistor 231 also includes an interlayer insulating layer 2314, the interlayer insulating layer 2314 covers the gate 2313 and the gate insulating layer 2312, the thin film transistor 231 also includes an interlayer dielectric layer 2315, and the interlayer dielectric layer 2315 is disposed on a side of the interlayer insulating layer 2314 away from the base substrate 21. Both the interlayer insulating layer 2314 and the interlayer dielectric layer 2315 are insulating materials, but the materials of the interlayer insulating layer 2314 and the interlayer dielectric layer 2315 can be different.

The source and drain are arranged on the surface of the interlayer dielectric layer 2315 away from the substrate 21, and the source and drain include a first source 2316 and a drain 2317, and the first source 2316 and drain 2317 are connected to the active layer 2311, for example, the first source electrode 2316 and the drain electrode 2317 are respectively connected to the two doped regions of the corresponding active layer 2311 through via holes.

A protection layer 2318 is provided on a side of the first source 2316 away from the base substrate 21, and the protection layer 2318 covers the first source 2316 and the drain 2317. A first planarization layer 24 is provided on the side of the source and drain away from the base substrate 21, the first planarization layer 24 is provided on the side of the protection layer 2318 away from the base substrate 21, the first planarization layer 24 covers the protection layer 2318, and the surface of the first planarization layer 24 away from the base substrate 21 is a plane.

In other embodiments, the source and drain may also include a second source (not shown in FIG. 1), and a second planarization layer (not shown in FIG. 1) is provided on the side of the second source away from the substrate 21, the second planarization layer covers the second source and the first planarization layer 24, and the second source is connected to the first source 2316 through a via hole.

Note that a buffer layer 22 is usually provided between the base substrate 21 and the thin film transistor 231.

A pixel defining layer 25 and a pixel layer 26 may be provided on the side of the driving backplane away from the base substrate 21, the pixel defining layer 25 has a plurality of openings 251, the pixel layer 26 includes a plurality of sub-pixels, and the plurality of sub-pixels are respectively arranged in the plurality of openings 251. The plurality of sub-pixels are distributed in an array on a side of the driving backplane away from the base substrate 21, and a specific sub-pixel may be located on a side of the first planarization layer 24 or the second planarization layer away from the base substrate 21. It should be noted that the sub-pixels may include red sub-pixels, green sub-pixels and blue sub-pixels according to different luminescent colors.

Each sub-pixel may include a first electrode 261, a light-emitting element 262 and a second electrode 263, the first electrode 261 is located on the surface of the driving backplane away from the base substrate 21, the light-emitting element 262 is disposed on the surface of the first electrode 261 away from the base substrate 21, and the second electrode 263 is disposed on the surface of the light-emitting element 262 away from the base substrate 21. The light-emitting layer can be driven to emit light through the first electrode 261 and the second electrode 263 to display images.

The first electrode 261 is connected to the first source 2316 or the second source. When the thin film transistor 231 only includes the first source 2316, the first electrode 261 is connected to the first source 2316, and the pixel defining layer 25 is provided to cover the first electrode 261 and the first planarization layer 24. When the thin film transistor 231 further includes the second source, the first electrode 261 is connected to the second source, and the pixel defining layer 25 is provided to cover the first electrode 261 and the fourth planarization layer.

The second electrode 263 can be used as a cathode, and the first electrode 261 can be used as an anode, and the light-emitting element 262 can be driven to emit light by applying a signal to the first electrode 261, and the specific light-emitting principle will not be described in detail here. The light-emitting element 262 may include an electroluminescent organic light-emitting material. For example, the light-emitting element 262 may include an auxiliary layer and a light-emitting layer sequentially stacked on the first electrode 261. The auxiliary layer may generally include a hole injection layer, a hole transport layer, an electron transport layer and electron injection layer. Generally, a pattern area is provided on the mask, and the auxiliary layer of sub-pixels of different colors and the light-emitting layer of sub-pixels of different colors are formed by evaporation and other processes.

In addition, the display panel 2 of the present disclosure may further include an encapsulation layer 27 disposed on a side of the pixel layer 26 away from the base substrate 21, so as to cover the pixel layer 26 and prevent water and oxygen erosion. The encapsulation layer 27 can be a single-layer or multi-layer structure, and the material of the encapsulation layer 27 can include organic or inorganic materials, which are not specifically limited here.

In this embodiment, the encapsulation layer 27 may include a first inorganic encapsulation layer 271, an organic encapsulation layer 272 and a second inorganic encapsulation layer 273, the first inorganic encapsulation layer 271 is disposed on the side of the pixel layer 26 away from the base substrate 21, the organic encapsulation layer 272 is disposed on a side of the first inorganic encapsulation layer 271 away from the base substrate 21, and the second inorganic encapsulation layer 273 is disposed on a side of the organic encapsulation layer 272 away from the base substrate 21. The inorganic encapsulation layer 271 and the second inorganic encapsulation layer 273 can be formed by vapor deposition, and the organic encapsulation layer 272 can be formed by inkjet printing and ink leveling.

The non-display area 202 is provided with a plurality of dams 203 that are successively away from the display area 201, and the plurality of dams 203 may include a first dam 2031 and a second dam 2032, the first dam 2031 is disposed around the display area 100, and the second dam 2032 is disposed around the first dam 2031.

As shown in FIG. 2, the mask 1 includes a mask body 12. When performing evaporation, the mask body 12 is generally arranged on the mask frame 11, and the fine mask 14 is arranged on the mask body 12. The mask frame 11 is provided therein with an evaporation hole (not shown in FIG. 2), the mask body 12 has a plurality of first openings 121 for preliminarily determining the evaporation area, and the fine mask 14 has a patterned third opening 141 for finally determining the pattern to be formed. The evaporation hole, the first opening 121 and the third opening 141 communicate with each other. During the evaporation process, the evaporation material is deposited on the surface of the driving backplane through the evaporation hole, the first opening 121 and the third opening 141 sequentially.

In conjunction with the display panel shown in FIG. 1, the display panel 2 has a display area 201 and a non-display area 202 located on the periphery of the display area 201. The pixel layer 26 of the display area is generally formed on the driving panel layer by layer through vapor deposition with the mask 1.

The pixel layer 26 located in the display area may generally include a plurality of red sub-pixels, a plurality of green sub-pixels and a plurality of blue sub-pixels. When forming the pixel layer 26 on the driving backplane, generally the blue sub-pixel light-emitting layer is evaporated first, then the red sub-pixel auxiliary layer is evaporated, then the red sub-pixel light-emitting layer is evaporated, then the green sub-pixel auxiliary layer is evaporated, and then the green sub-pixel light-emitting layer is evaporated to form the red sub-pixels, green sub-pixels and blue sub-pixels.

It should be noted that the red sub-pixel, multiple green sub-pixels and multiple blue sub-pixels are usually arranged in an array, so the red sub-pixel light-emitting layer, the green sub-pixel light-emitting layer, the blue sub-pixel light-emitting layer, the red sub-pixel light-emitting layer, the red sub-pixel auxiliary layer and the green sub-pixel auxiliary layer are all patterned coatings composed of multiple graphic units arranged in an array.

It can be understood that each of the patterns to be formed includes a plurality of graphic units arranged at intervals, and there are multiple types of graphic units, and the various graphic units are classified into graphic units of the auxiliary layer and graphic units of the light-emitting layer. The graphic unit of the auxiliary layer includes the graphic unit of the red sub-pixel auxiliary layer, and the graphic unit of the green sub-pixel auxiliary layer, and the graphic units of the light-emitting layer includes the graphic unit of the red sub-pixel light-emitting layer, the graphic unit of the green sub-pixel light-emitting layer, and the blue sub-pixel light-emitting layer graphic unit.

The red pixel auxiliary layer is located on the side of the red pixel light-emitting layer close to the driving backplane, and is used for guiding light when the red pixel emits light. The green pixel auxiliary layer is located on the side of the green pixel light-emitting layer close to the driving backplane, and is used for guiding light when the green pixel emits light. Due to the blue pixel material, when the blue pixel emits light, the auxiliary pixel is not required to conduct light, so there is no need to make an auxiliary blue auxiliary layer.

Since the red sub-pixel light-emitting layer, green sub-pixel light-emitting layer, blue sub-pixel light-emitting layer, red sub-pixel auxiliary layer, and green sub-pixel auxiliary layer are evaporated in different evaporation chambers, it is usually necessary to monitor the evaporation precision of the red sub-pixel light-emitting layer, the green sub-pixel light-emitting layer, the blue sub-pixel light-emitting layer, the red sub-pixel auxiliary layer, and the green sub-pixel auxiliary layer.

Based on this, a red sub-pixel light-emitting layer, a green sub-pixel light-emitting layer, a blue sub-pixel light-emitting layer, a red sub-pixel auxiliary layer, and a green sub-pixel auxiliary layer are usually formed on the part of the driving backplane located in the non-display area 202, and the red sub-pixel light-emitting layer, the green sub-pixel light-emitting layer, the blue sub-pixel light-emitting layer, the red sub-pixel auxiliary layer, and the green sub-pixel auxiliary layer located in the non-display area 202 are configured to be overlapped with each other.

By monitoring the vapor deposition thicknesses of the red sub-pixel light-emitting layer, green sub-pixel light-emitting layer, blue sub-pixel light-emitting layer, red sub-pixel auxiliary layer, and green sub-pixel auxiliary layer in the non-display area 202, the evaporation thicknesses of the red sub-pixel light-emitting layer, the green sub-pixel light-emitting layer, the blue sub-pixel light-emitting layer, the red sub-pixel auxiliary layer, and the green sub-pixel auxiliary layer in the display area can be determined.

The mask body 12 has a pattern area 102 and a light-shielding area 101 around the pattern area 102, the light-shielding area 101 is used to correspond to the non-display area 202 of the display panel 2, and the pattern area 102 corresponds to the display area. The pattern area 102 includes a plurality of first openings 121 arranged at intervals. The shapes and sizes of the first openings 121 on different mask main bodies 12 respectively correspond to the graphic units of the red sub-pixel light-emitting layer, the graphic units of the green sub-pixel light-emitting layer, the graphic units of the blue sub-pixel light-emitting layer, the graphic units of the red sub-pixel auxiliary layer, and the graphic units of the green sub-pixel auxiliary layer.

It can be understood that, because the red sub-pixel light-emitting layer, green sub-pixel light-emitting layer, blue sub-pixel light-emitting layer, red sub-pixel auxiliary layer, and green sub-pixel auxiliary layer located in the non-display area 202 are configured to be overlapped with each other, Pattern areas 102 corresponding to the red sub-pixel light-emitting layer, the green sub-pixel light-emitting layer, the blue sub-pixel light-emitting layer, the red sub-pixel auxiliary layer, and the green sub-pixel auxiliary layer need to be fabricated on different mask bodies 12.

Taking the blue sub-pixel light-emitting layer as an example for illustration, the light-shielding area 101 of the mask body 12 only has the first opening 121 for accuracy test for determining the vapor deposition position of the blue sub-pixel light-emitting layer. The positions of the green sub-pixel light-emitting layer, the blue sub-pixel light-emitting layer, the red sub-pixel auxiliary layer, and the green sub-pixel auxiliary layer are different, and the first openings 121 for accuracy test for determining the vapor deposition positions of the green sub-pixel light-emitting layer, the blue sub-pixel light-emitting layer, the red sub-pixel auxiliary layer, and the green sub-pixel auxiliary layer are all formed in the light-shielding areas 101 of their respective mask bodies 12, such that the mask bodies 12 cannot be shared, the number of the mask bodies 12 is large, and the cost for manufacturing the pixel layers is high.

The size of the openings corresponding to the red sub-pixel light-emitting layer, the green sub-pixel light-emitting layer, the blue sub-pixel light-emitting layer, the red sub-pixel auxiliary layer, and the green sub-pixel auxiliary layer in the pattern area 102 of the mask body 12 are relatively small, and the mask body 12 is usually relatively thick, resulting in the processing of the mask body 12 relatively difficult.

As shown in FIG. 3, the driving backplane is located above the mask bar 13. During the evaporation process, a magnetic spacer 3 will be placed above the driving backplane. The magnetic spacer 3 has a magnetic force and generates a magnetic attractive force on the mask 1, such that the mask 1 and the magnetic spacer 3 fix the driving backplane therebetween.

During the evaporation process, it is necessary to avoid the movement of the driving backplane or the mask 1, so as to ensure the accuracy of evaporation. Due to the difference in the design of the magnetic attractive force unit of different evaporation machines, for example, the magnetic force of the first area 122 and the second area 123 of the mask body 12 are different, and the mask 1 cannot be shared in order to match the magnetic force of the evaporation machine. Finally, on the same vapor deposition machine, the attractive flatness difference of the mask 1 is also difficult to solve.

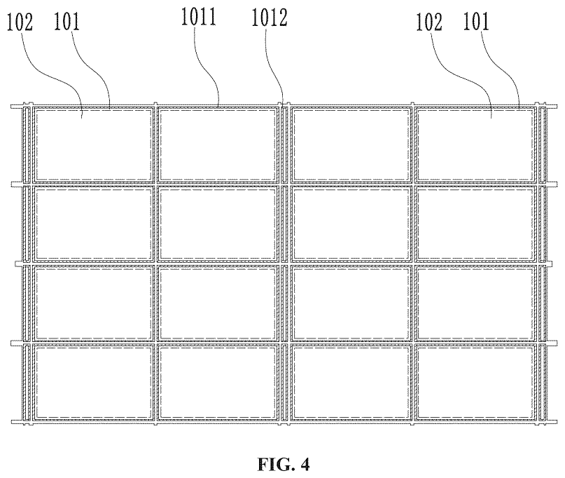

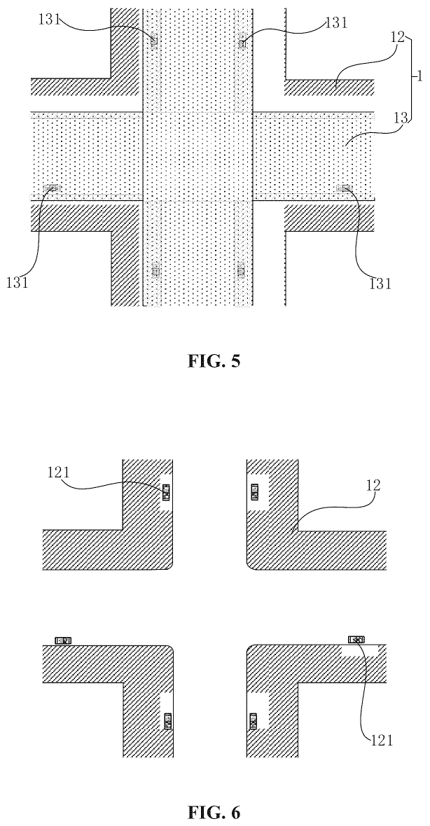

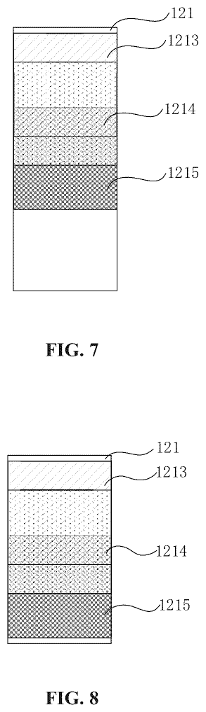

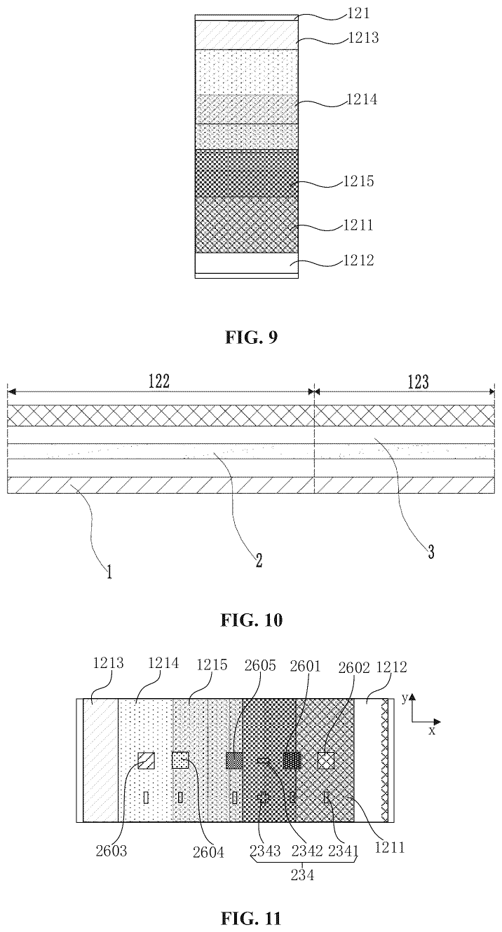

As shown in FIGS. 4 to 9, embodiments of the present disclosure provide a mask. The mask 1 is used to form different patterns to be formed on the display panel. Each pattern to be formed includes a plurality of graphic units arranged at intervals, and the graphic units are arranged in multiple types. The mask 1 includes a mask body 12 and a mask bar 13, the mask body 12 is provided with a plurality of first openings 121 at intervals; the mask bar 13 is provided with a plurality of second openings 131 corresponding one to one to the plurality of first openings 121 at intervals, and the mask bar 13 is provided on one side of the mask body 12, the position, shape and size of the second opening 131 are the same as those of any type of the graphic units, and the orthographic projection of the second openings 131 corresponding to the multiple types of graphic units on the mask body 12 is located in the first opening 121.

By providing the mask with a common first opening 121 on the mask body 12, and is equipping with the mask bars 13 having different second openings 131, to form a mask 1 suitable for different patterns to be formed, the number of mask body 12 is reduced. Moreover, the size of the first opening 121 is increased, and even in a thick mask body 12, the first opening 121 is relatively easy to produce, and although the second opening 131 is small, the mask bar 13 is relatively thin, so the processing difficulty is relatively small. In summary, when the number of mask body 12 is reduced and the processing difficulty of a single mask is reduced, the cost of the mask 1 required for processing different graphic units of the pattern to be formed is relatively low.

The mask 1 includes a mask body 12 and a mask bar 13, and the mask bar 13 is located on the mask body 12. The mask body 12 has a plurality of first openings 121 arranged at intervals. The shapes and sizes of the plurality of first openings 121 are exactly the same. The mask bar 13 has a plurality of second openings 131. The orthographic projection of the second opening 131 on the mask body 12 is located in the first opening 121, that is, the second opening 131 communicates with the first opening 121. During the evaporation process, the driving backplane is placed above the mask bar 13, and the mask bar 13 is opposite to the driving backplane, and the evaporation material passes through the first opening 121, the second opening 131 and a third opening 141 of a fine mask 14 in sequence, to be deposited onto the surface of the driving backplane.

The positions of the pattern areas 102 corresponding to different patterns to be formed are different, and the positions of at least some graphic units in different patterns to be formed are different, and the positions of at least part of the second openings 131 in different pattern areas 102 are different. Each pattern to be formed includes a plurality of graphic units arranged at intervals. The mask 1 includes a light-shielding area 101 corresponding to the non-display area and a pattern area 102 corresponding to the display area. Adjacent orthographic projections in one first opening 121 of the second openings 131 corresponding to the multiple types of the graphic units in the light-shielding area 101 are partly overlapped or not overlapped. Adjacent second openings 131 corresponding to part types of the graphic units in the pattern area 102 are partly overlapped or not overlapped, and the second openings 131 corresponding to another part types of the graphic units are overlapped with the second openings 131 corresponding to part types of the graphic units.

The orthographic projection of the second opening 131 corresponding to various graphic units in the first opening 121 will be described below in conjunction with the pixel layer of the display panel.

Define the graphic unit of the red sub-pixel auxiliary layer as the first graphic unit 2601, the graphic unit of the green sub-pixel auxiliary layer as the second graphic unit 2602, the graphic unit of the red sub-pixel light-emitting layer as the third graphic unit 2603, the graphic unit of the green sub-pixel light-emitting layer as the fourth graphic unit 2604, and the graphic unit of the blue sub-pixel light-emitting layer as the fifth graphic unit 2605. Define the orthographic projection of the second opening 131 corresponding to the graphic unit of the red sub-pixel auxiliary layer in the first opening 121 as the first orthographic projection 1211, the orthographic projection of the second opening 131 corresponding to the graphic unit of the green sub-pixel auxiliary layer in the first opening 121 as the second orthographic projection 1212, the orthographic projection of the second opening 131 corresponding to the graphic unit of the red sub-pixel light-emitting layer in the first opening 121 as the third orthographic projection 1213, the orthographic projection of the second opening 131 corresponding to the graphic unit of the green sub-pixel light-emitting layer in the first opening 121 as the fourth orthographic projection 1214, the orthographic projection of the second opening 131 corresponding to the graphic unit of the blue sub-pixel light-emitting layer in the first opening 121 as the fifth orthographic projection 1215.

It should be noted that the distribution of the first orthographic projection 1211, the second orthographic projection 1212, the third orthographic projection 1213, the fourth orthographic projection 1214, and the fifth orthographic projection 1215 in the pattern area 102 is completely corresponding to that of the first graphic unit 2601, the second graphic unit 2602, the third graphic unit 2603, the fourth graphic unit 2604 and the fifth graphic unit 2605 in the display area that is, it is completely corresponding to the distribution of the sub-pixels in the display area. For example, the sub-pixels in the existing display area are distributed in hexagonal crystal, tripod shape, circle and diamond shape, then the first orthographic projection 1211, the second orthographic projection 1212, the third orthographic projection 1213, the fourth orthographic projection 1214 and the fifth orthographic projection 1215 can be distributed in the pattern area 102 in the form of hexagonal crystal, tripod, circle and diamond.

In the display area, the graphic units of the red sub-pixel auxiliary layer, the graphic units of the green sub-pixel auxiliary layer and the graphic units of the blue sub-pixel light-emitting layer are generally arranged at intervals. In the pattern areas 102 of different masks 1, the first orthographic projections 1211, the second orthographic projections 1212, and the third orthographic projections 1213 may partially overlap or may not overlap each other. The fourth orthographic projection 1214 is completely coincident with the first orthographic projection 1211; and the fifth orthographic projection 1215 is completely coincident with the second orthographic projection 1212.

When the distance between the graphic unit of the red sub-pixel auxiliary layer, the graphic unit of the green sub-pixel auxiliary layer and the graphic unit of the blue sub-pixel light-emitting layer is relatively large, then the adjacent first orthographic projection 1211, the second orthographic projection 1212, and the third orthographic projection 1213 does not overlap with each other. When the distance between the graphic unit of the red sub-pixel auxiliary layer, the graphic unit of the green sub-pixel auxiliary layer and the graphic unit of the blue sub-pixel light-emitting layer is small, then the adjacent first orthographic projection 1211, the second orthographic projection 1212, and the third orthographic projection 1213 of the pattern area 102 of the mask 1 partially overlap with each other.

In the non-display area, the graphic unit of the red sub-pixel auxiliary layer, the graphic unit of the green sub-pixel auxiliary layer, the graphic unit of the red sub-pixel light-emitting layer, the graphic unit of the green sub-pixel light-emitting layer, and the graphic unit of the blue sub-pixel light-emitting layer are generally disposed at intervals. In the light-shielding regions 101 of different masks 1, the first orthographic projection 1211, the second orthographic projection 1212, the third orthographic projection 1213, the fourth orthographic projection 1214, and the fifth orthographic projection 1215 may partially overlap with each other, can also be non-overlapping.

When the distance between the graphic unit of the red sub-pixel auxiliary layer, the graphic unit of the green sub-pixel auxiliary layer, the graphic unit of the red sub-pixel light-emitting layer, the graphic unit of the green sub-pixel light-emitting layer, and the graphic unit of the blue sub-pixel light-emitting layer is small, the adjacent first orthographic projection 1211, the second orthographic projection 1212, the third orthographic projection 1213, the fourth orthographic projection 1214, and the fifth orthographic projection 1215 are partially overlapped. When the distance between the graphic unit of the red sub-pixel auxiliary layer, the graphic unit of the green sub-pixel auxiliary layer, the graphic unit of the red sub-pixel light-emitting layer, the graphic unit of the green sub-pixel light-emitting layer, and the graphic unit of the blue sub-pixel light-emitting layer is large, the adjacent first orthographic projection 1211, the second orthographic projection 1212, the third orthographic projection 1213, the fourth orthographic projection 1214, and the fifth orthographic projection 1215 do not overlap each other.

It should be noted that because the second openings 131 corresponding to the graphic units in the pattern area 102 overlap each other in the first opening 121, the sum of the areas of the orthographic projections in the first opening 121 of the second openings 131 corresponding to the various graphic units in the light-shielding area 101 is generally greater than the sum of the areas of the orthographic projections in the first opening 121 of the second openings 131 corresponding to the various graphic units in the pattern area 102.

However, regardless of the light-shielding area 101 or the pattern area 102, the specification of the first opening 121 can always be configured to be the same, and the first opening 121 of the light-shielding area 101 is used as a sample. In this embodiment, the orthographic projections of the second openings 131 corresponding to various graphic units in the first opening 121 are arranged in the first opening 121 along the first direction, and the size of the first opening 121 along the first direction is greater than or equal to the sum of the of the sizes of the orthographic projections of the second openings 131 corresponding to various graphic units in the first opening 121.

It is also possible to configure the specification of the first opening 121 of the light-shielding area 101 different from that of the first opening 121 of the pattern area 102. The size of the first opening 121 located in the light-shielding area 101 along the first direction is greater than or equal to the sum of the of the sizes of the orthographic projections of the second openings 131 corresponding to all types of the graphic units in the first opening 121, and the size of the first opening 121 located in the pattern area 102 along the first direction is greater than or equal to the sum of the of the sizes of the orthographic projections of the second openings 131 corresponding to part types of the graphic units in the first opening 121. It can be understood that the size of the first opening 121 of the light shielding area 101 is smaller than the size of the first opening 121 of the pattern area 102.

The mask bars may include a plurality of mask bars 13 with different magnetic permeability, and the multiple mask bars 13 with different magnetic permeability are disposed on different regions of the mask body 12. As shown in FIG. 10, the mask body 12 includes a first region 122 and a second region 123 which are adjacently arranged. When the magnetic force of the first region 122 is weak and causes the driving backplane to sag, while the magnetic force of the second region is normal and the driving backplane is well attracted to the vapor deposition machine, the mask bar 13 with strong magnetic force can be disposed in the first area 122, and the mask bar 13 with weak magnetic force can be disposed in the second area 123 to ensure the flatness of the attraction of the driving backplane.

It should be noted that the mask bars 13 with different magnetic permeability can include mask bars made of iron-nickel-cobalt alloy and stainless steel. The mask bars made of iron-nickel-cobalt alloy have stronger magnetic permeability, and those made of stainless steel have weak magnetic permeability, so the mask bar made of iron-nickel-cobalt alloy can be disposed in the first region 122, and the mask bar made of stainless steel can be disposed in the second region 123.

Because of the difference in magnetic force, the mask 1 will be deformed due to uneven force, which will cause displacement of the corresponding part of the driving backplane attached to the deformed position of the mask bar 13, and then cause attraction wrinkles on the driving backplane. In order to prevent the mask 1 from being deformed, a first groove 1011 is provided on the mask body 12, and the first groove 1011 is arranged around the pattern area 102 and located in the light-shielding area 101. The first groove can release the stress on the mask 1, and the strain caused by uneven stress, and can reduce the deformation of the mask 1.

It should be noted that the first opening 121 can be disposed in the first groove 1011, or can be disposed in a region of the mask body 12 where the light shielding region 101 is not provided with the first groove 1011.

In addition, when the distance between two adjacent first grooves 1011 is large, a second groove 1012 may also be provided between two adjacent first grooves 1011. The stress of the mask 1 located between the two first grooves 1011 can be released through the second grooves 1012, preventing the strain of this part due to uneven stress, and further reducing the deformation of the entire mask 1. The second groove 1012 can be configured as a closed structure.

Embodiments of the present disclosure provide a display panel. The pattern to be formed on the display area of the display panel is prepared by any of the above-mentioned masks. Different patterns to be formed are prepared and formed by different masks. The positions, shapes and sizes of the second openings 131 of different masks and the size are the same as the positions, shapes and sizes of the corresponding graphic unit.

As shown in FIG. 11, the pattern to be formed is disposed on the driving backplane, and the graphic units include a first graphic unit 2601, a second graphic unit 2602, a third graphic unit 2603, a fourth graphic unit 2604 and a fifth graphic unit 2605. The third graphic unit 2603, the fourth graphic unit 2604, the fifth graphic unit 2605, the first graphic unit 2601, and the second graphic unit 2602 may be sequentially arranged along the first direction.

In order to ensure that the pattern area 102 of the mask is aligned with the display area of the display panel, and the light-shielding area 101 of the mask is aligned with the frame area of the display panel, the driving backplane is provided with an alignment mark 234 for aligning the second opening 131 with each graphic unit, and the alignment mark 234 is located in the non-display area.

The alignment mark 234 includes at least one first alignment mark 2341 arranged along the first direction, second alignment marks 2342 arranged along the second direction and corresponding to the five graphic units one-to-one, and a third alignment mark 2343 for aligning the position of the first alignment mark 2341 and the position of the second alignment mark 2342. The first alignment mark 2341 is disposed between the fifth graphic unit 2605 and the first graphic unit 2601, and the five second alignment marks 2342 are respectively disposed on the same side of the first graphic unit 2601, the second graphic unit 2602, the third graphic unit 2603, the fourth graphic unit 2604, and the fifth graphic unit 2605 along the second direction. The third alignment mark 2343 is located on the same line as the five second alignment marks 2342 along the second direction, and the third alignment mark 2343 is disposed between the first alignment mark 2341 corresponding to the fifth graphic unit 2605 and the first alignment mark 2341 corresponding to the first graphic unit 2601.

It should be noted that the first direction is the x direction in FIG. 11, and the second direction is the y direction in FIG. 11.

Specifically, the alignment mark 234 is a concave portion disposed on a metal layer. Because the gate 2313 and the source and drain of the thin film transistor 231 in the display area are usually made of metal, and the alignment mark 234 is located in the non-display area, the driving backplane of the non-display area can include the first metal layer 232 and the second metal layer 233, wherein the first metal layer 232 and the gate electrode 2313 are provided in the same layer with the same material, a recess can be provided on the first metal layer 232 to form the alignment mark 234; a recess can also be provided on the second metal layer 233 to form the alignment mark 234; and recesses can also be provided on both the first metal layer 232 and the second metal layer 233 to form the alignment mark 234.

The first graphic unit 2601, the second graphic unit 2602, the third graphic unit 2603, the fourth graphic unit 2604, and the fifth graphic unit 2605 that make up the pixel layer on the display panel are formed with high precision, so that the display performance of each sub-pixel of the same color is substantially the same, thereby improving the display effect of the display panel.

Embodiments of the present disclosure provide a display device. The display device includes the display panel described in any one of the above embodiments of the present disclosure. For the display device, reference may also be made to the specific structure and beneficial effects of the display panel, which will not be repeated here.

The display device can be a traditional electronic device, such as a mobile phone, a computer, a television, and a video recorder, or an emerging wearable device, such as a virtual reality device and an augmented reality device, which are not listed here.

It should be noted that, in addition to the display panel, the display device also includes other necessary components and component, taking a mobile phone as an example, specifically such as a casing, a circuit board, etc., and those skilled in the art can made corresponding supplements according to the particular use requirement of the display device, which will not be repeated here.

Other embodiments of the present disclosure will be readily apparent to those skilled in the art from consideration of the specification and practice of the invention disclosed herein. This application is intended to cover any modification, use or adaptation of the present disclosure, and these modifications, uses or adaptations follow the general principles of the present disclosure and include common knowledge or conventional technical means in the technical field not disclosed in the present disclosure. The specification and examples are to be considered exemplary only, with the true scope and spirit of the disclosure indicated by the appended claims.

1. A mask, used to form different patterns to be formed on a display panel, each of the patterns to be formed comprises a plurality of graphic units arranged at intervals, and the graphic units are arranged in multiple types, wherein, the mask comprises:
a mask body, provided with a plurality of first openings at intervals; and
a mask bar, provided with a plurality of second openings at intervals corresponding one-to-one to the plurality of first openings, the mask bar is disposed on a side of the mask body, the second openings have same position, shape and size with any one type of the graphic units, and orthographic projections on the mask body of the second openings corresponding to the multiple types of the graphic units are located in the first openings.

2. The mask according to claim 1, wherein the mask comprises a light-shielding area corresponding to a non-display area, adjacent orthographic projections in one first opening of the second openings corresponding to the multiple types of the graphic units in the light-shielding area are partly overlapped or not overlapped.

3. The mask according to claim 2, wherein the mask comprises a pattern area corresponding to a display area, adjacent second openings corresponding to part types of the graphic units in the pattern area are partly overlapped or not overlapped, and the second openings corresponding to another part types of the graphic units are overlapped with the second openings corresponding to part types of the graphic units.

4. The mask according to claim 3, wherein the orthographic projections of the second openings corresponding to the multiple types of graphic units in the first opening are arranged along a first direction, and a size in the first direction of the first opening is greater than or equal to a sum of sizes in the first direction of the orthographic projections of the second openings corresponding to the multiple types of graphic units.

5. The mask according to claim 4, wherein the size in the first direction of the first opening located in the pattern area is greater than or equal to a sum of sizes in the first direction of the orthographic projections of the second openings corresponding to part types of the graphic units.

6. The mask according to claim 1, wherein the mask bar comprises a plurality of mask bars with different magnetic permeability, and the plurality of mask bars with different magnetic permeability are arranged on different regions of the mask body.

7. The mask according to claim 6, wherein the mask body comprises a first region and a second region adjacently arranged, and the mask bars with different magnetic permeability comprises a iron-nickel-cobalt alloy mask bar and a stainless steel mask bar, the iron-nickel-cobalt alloy mask bar is disposed in the first region, and the stainless steel mask bar is disposed in the second region.

8. The mask according to claim 3, wherein the mask body is provided with a first groove, the first groove is arranged in the light-shielding area, the first groove is disposed around the pattern area, and is located in the light-shielding area.

9. The mask according to claim 8, wherein a second groove is provided between two adjacent first grooves.

10. A display panel, in which patterns to be formed are prepared by a mask, wherein each of the patterns to be formed comprises a plurality of graphic units arranged at intervals, and the graphic units are arranged in multiple types, wherein, the mask comprises:
a mask body, provided with a plurality of first openings at intervals; and
a mask bar, provided with a plurality of second openings at intervals corresponding one-to-one to the plurality of first openings, the mask bar is disposed on a side of the mask body, the second openings have same position, shape and size with any one type of the graphic units, and orthographic projections on the mask body of the second openings corresponding to the multiple types of the graphic units are located in the first openings,
wherein different patterns to be formed are prepared by different masks, and the second openings of the different masks have same position, shape and size with corresponding graphic units.

11. The display panel according to claim 10, wherein the display panel comprises a driving backplane, the patterns to be formed are disposed on the driving backplane, and the multiple types of graphic units comprise graphic units of an auxiliary layer and graphic units of a light-emitting layer; and
the display panel further comprises a display area, in the display area, the graphic units of the light-emitting layer are not overlapped with each other, and the graphic units of the auxiliary layer are disposed between the graphic units of the light-emitting layer and the driving backplane.

12. The display panel according to claim 11, wherein the display panel further comprises a non-display area, and in the non-display area, the graphic units of the auxiliary layer and the graphic units of the light-emitting layer are not overlapped with each other.

13. The display panel according to claim 10, wherein an alignment mark for aligning the second openings with the graphic units is provided on the driving backplane, and the alignment mark is located in the non-display area.

14. The display panel according to claim 13, wherein the alignment mark comprises:
at least one first alignment mark arranged along the first direction;
a plurality of second alignment marks corresponding to the multiple types of graphic units one by one, the plurality of second alignment marks are arranged along a second direction, and the second direction is intersected with the first direction; and
a third alignment mark, the third alignment mark is located at an intersection of a virtual line in the first direction passing the first alignment mark and a virtual line in the second direction passing the second alignment marks.

15. The display panel according to claim 13, wherein the driving backplane comprises a metal layer in the non-display area, and the alignment mark is a recess provided on the metal layer.

16. The display panel according to claim 15, wherein the driving backplane comprises a base substrate, a gate, and source and drain electrodes in the display area, the gate is disposed on a side of the base substrate, the source and drain electrodes are disposed on a side of the gate away from the base substrate, the metal layer comprises a first metal layer and a second metal layer, the first metal layer is disposed in a same layer with a same material with the gate, the second metal layer is disposed in a same layer with a same material with the source and drain electrodes, and the recess is disposed in the first metal layer and/or the second metal layer.

17. A display device, comprising a display panel, in which patterns to be formed are prepared by a mask, wherein each of the patterns to be formed comprises a plurality of graphic units arranged at intervals, and the graphic units are arranged in multiple types, wherein, the mask comprises:
a mask body, provided with a plurality of first openings at intervals; and
a mask bar, provided with a plurality of second openings at intervals corresponding one-to-one to the plurality of first openings, the mask bar is disposed on a side of the mask body, the second openings have same position, shape and size with any one type of the graphic units, and orthographic projections on the mask body of the second openings corresponding to the multiple types of the graphic units are located in the first openings,
wherein different patterns to be formed are prepared by different masks, and the second openings of the different masks have same position, shape and size with corresponding graphic units.

18. The display device according to claim 17, wherein the mask comprises a light-shielding area corresponding to a non-display area, adjacent orthographic projections in one first opening of the second openings corresponding to the multiple types of the graphic units in the light-shielding area are partly overlapped or not overlapped.

19. The display device according to claim 18, wherein the mask comprises a pattern area corresponding to a display area, adjacent second openings corresponding to part types of the graphic units in the pattern area are partly overlapped or not overlapped, and the second openings corresponding to another part types of the graphic units are overlapped with the second openings corresponding to part types of the graphic units.

20. The display device according to claim 19, wherein the orthographic projections of the second openings corresponding to the multiple types of graphic units in the first opening are arranged along a first direction, and a size in the first direction of the first opening is greater than or equal to a sum of sizes in the first direction of the orthographic projections of the second openings corresponding to the multiple types of graphic units.
